(19) United States
(12) Patent Application Publication
(10) Pub. No.: US 2016/0191109 A1
(43) Pub. Date: Jun. 30, 2016

(54) SINGLE POLE DOUBLE THROW SWITCH

(71) Applicant: LG INNOTEK CO., LTD., Seoul (KR)

(72) Inventors: Hye Sun LEE, Seoul (KR); Young Hun PARK, Seoul (KR)

(21) Appl. No.: 14/968,636

(22) Filed: Dec. 14, 2015

(30) Foreign Application Priority Data
Dec. 24, 2014 (KR) 10-2014-0188435

(51) Int. Cl. H04B 1/56; H03H 7/38

(52) U.S. Cl. CPC H04B 1/56; H03H 7/38

(57) ABSTRACT

An SPDT switch configured to separate a transmission signal and a reception signal in order to transmit and receive signals in same frequency through an antenna, wherein difference between antenna impedance and reception terminal impedance of the reception unit is less than difference between antenna impedance and transmission terminal impedance, and difference between the transmission terminal impedance and the antenna impedance is less than a difference between the transmission terminal impedance and the reception terminal impedance. The transmission and reception terminal impedance may be specified using a pattern of an RF signal line printed on a PCB. The SPDT switch has more competitive price relating to development of a wireless system because a pattern printed on the PCB is used, and is easy to be applied since passive elements in simple structure are used, therefore having no risk of failure due to ESD.

### CROSS-REFERENCE TO RELATED APPLICATIONS

Pursuant to 35 U.S.C. §119 (a), this application claims the benefit of earlier filing dates and rights of priority to Korean Patent Application No. 10-2014-0188435, filed on Dec. 24, 2014, and the contents of which are hereby incorporated by references in their entirety.

### BACKGROUND OF THE INVENTION

1. Field of the Invention

The present disclosure relates to an SPDT (Single Pole Double Throw) switch, and more particularly, to an SPDT switch that separates transmission signals and reception signals, in order to transmit and receive a signal in the same frequency in an RF (Radio Frequency) system transmitting and receiving wireless signals through an antenna.

2. Description of Related Art

Various techniques to separate transmission and reception signals by electrically switching are currently available according to separation characteristics thereof, for example, SPST (Single-Pole-Single-Throw), SPDT (Single-Pole-Double-Throw), DPST (Double-Pole-Single-Throw), and DPDT (Double-Pole-Double-Throw).

The switch according to each of such methods may be composed using a separate circuit, or may be compose in an IC (Integrated Circuit) with a single chip. The switch performs electrical switching operation using an active element such as a pin diode.

However, electrical current is consumed when performing the switching operation by applying voltage to active element (pin diode), and an additional chip such as a varistor is required to compensate a disadvantageous weakness in ESD (Electro Static Discharge).

In addition, the production cost may increase, in a case where various types of active elements, depending on the applications, are used to separate transmission signals and reception signals.

That is, use of the active elements such as the pin diode to separate by electrically switching transmission and reception signals may cause various problems in that the circuit design becomes complicated, energy is consumed, and the production cost is increased.

### SUMMARY

Therefore, the present disclosure is conceived in order to remedy such problems as in the above. One purpose of the present disclosure is to separate signals using impedance difference between a transmission side and a reception side, when separating signals received and transmitted through an antenna in the same frequency. In addition, another purpose of the present disclosure is to obtain the same effect as that of active elements, even when passive elements are used.

In order to achieve the aforementioned purposes, in a general aspect of the present disclosure, there is provided a SPDT switch configured to transmit and receive signals in a same frequency through an antenna, the SPDT switch comprising: a reception unit configure to receive a signal through the antenna; and a transmission unit configured to transmit a signal through the antenna.

In some exemplary embodiments, a difference between an antenna impedance and a reception terminal impedance of the reception unit may be less than a difference between the antenna impedance and a transmission terminal impedance of the transmission unit, and a difference between the transmission terminal impedance and the antenna impedance may be less than a difference between the transmission terminal impedance and the reception terminal impedance.

In some exemplary embodiments, the transmission terminal impedance and the reception terminal impedance may be specified depending on a form or characteristic of an RF signal line printed on a PCB (Printed Circuit Board).

In some exemplary embodiments, the transmission terminal impedance may be and the reception terminal impedance may be 35Ω.

In some exemplary embodiments, the transmission unit may include: a first impedance matching unit configured to match the antenna impedance and the transmission terminal impedance; and a first switching element configured to remove an RF signal of an RF signal line by being switched contingent upon appliance of electricity.

In some exemplary embodiments, the reception unit may include: a second impedance matching unit configured to match the antenna impedance and the reception terminal impedance; and a second switching element configured to remove an RF signal of an RF signal line by being switched contingent upon appliance of electricity.

In some exemplary embodiments, the SPOT switch may further comprise: a first DC blocking capacitor configured to remove DC component of a signal transmitted from a transmission port; and a second DC blocking capacitor configured to remove DC component of a signal received through the antenna.

In some exemplary embodiments, the first impedance matching unit and the second impedance matching unit may perform impedance matching using a combination of an inductor and a capacitor.

According to an exemplary embodiment of the present disclosure, a same frequency signal transmitted and received through a single antenna may be separated using impedance difference between a transmission terminal and a reception terminal. The impedance difference may be implemented using a pattern printed on the PCB (Printed Circuit Board).

According to an exemplary embodiment of the present disclosure, the same operation as that of an active circuit may be implemented, even without using the active element. In addition, various advantageous effects as in the following may be obtained:

(1) The SPOT switch according to an exemplary embodiment of the present disclosure may have more competitive price relating to development of a wireless system, because a pattern printed on the PCB is used.

(2) The SPOT switch according to an exemplary embodiment of the present disclosure may be produced in less time, because no active element is used, and therefore a separate chip mount process and inspection is not required.

(3) The SPDT switch according to an exemplary embodiment of the present disclosure may be modified according the frequencies and applications in use, and may be employed in various applications.

(4) The SPDT switch according to an exemplary embodiment of the present disclosure has a simple structure, and therefore is easy to be applied. In addition, since passive elements are used, there is no risk of failure due to ESD.

### BRIEF DESCRIPTION OF THE DRAWINGS

FIG. 1 is an exemplary view illustrating an SPDT switch according to an exemplary embodiment of the present disclosure.

FIGS. 2 and 3 are exemplary views illustrating an SPDT switch implemented using a PCB (Printed Circuit Board).

FIGS. 4A and 4B are exemplary views to describe operations of a first switching element and a second switching element.

FIGS. 5A and 513 are exemplary views illustrating S-parameter graphs in relation to transmission and reception operations.

### DETAILED DESCRIPTION

Hereinafter, an exemplary embodiment of the present disclosure will be described in detain with reference to the enclosed drawings.

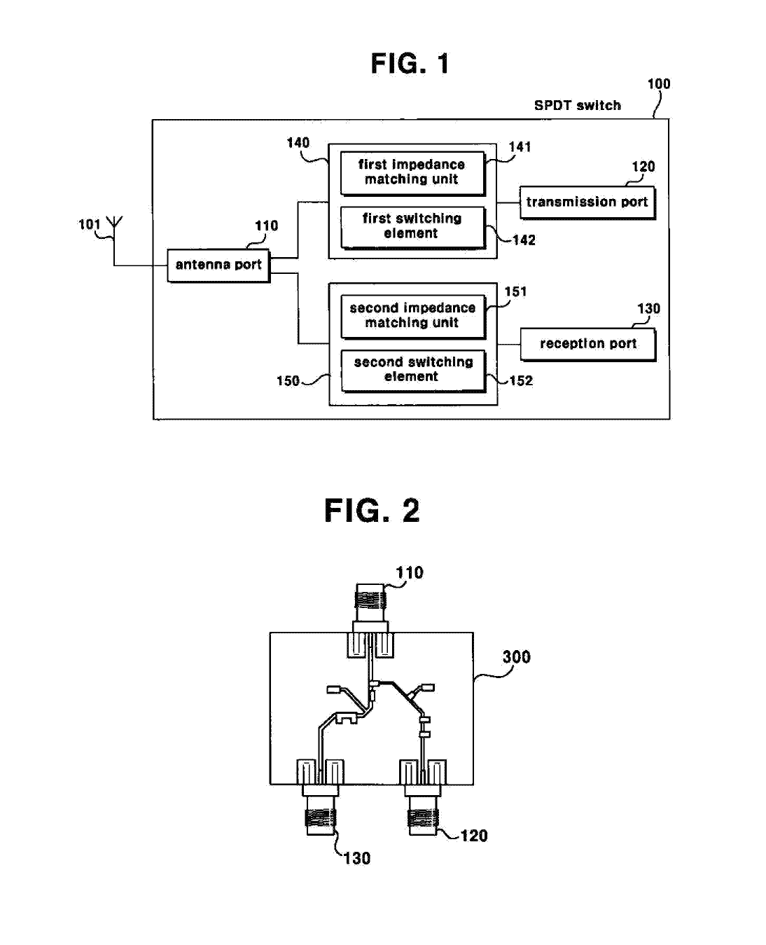

Referring to FIG. 1, the SPDT switch (100) according to an exemplary embodiment of the present disclosure may include an antenna port (110) connected to an antenna (101), a transmission port (120) receiving input of an RF signal to be transmitted through the antenna (101), a reception port (130) outputting an RF signal received through the antenna (101), a transmission unit (140) transmitting an RF signal inputted through the transmission port (120) to the antenna port (110), and a reception unit (150) transmitting an RF signal inputted through the antenna port (110) to the reception port (130). The SPDT switch (100) may transmit and receive an RF signal having a same frequency through the antenna (101).

The transmission unit (140) has a transmission terminal impedance, and the reception unit (150) has a reception terminal impedance, respectively. Each of the transmission terminal impedance and the reception terminal impedance is configured to satisfy impedance restriction conditions as follows:

(1) A difference between an antenna impedance and a reception terminal impedance is less than a difference between the antenna impedance and a transmission terminal impedance.

(2) A difference between the transmission terminal impedance and the antenna impedance is less than a difference between the transmission terminal impedance and the reception terminal impedance.

For example, the transmission terminal impedance may be set as 75Ω, and the reception terminal impedance may be set as 35Ω.

The antenna impedance is generally 50Ω. In such case, the difference between the antenna impedance and the reception terminal impedance may be 15Ω (50-35), and the difference between the antenna impedance and the transmission terminal impedance may be 25Ω (75-50). Therefore, the first impedance restriction condition may be satisfied.

In addition, the difference between the transmission terminal impedance and the antenna impedance may be 25Ω (75-50), and the difference between the transmission terminal impedance and the reception terminal impedance may be 40Ω (75-35). Therefore, the second impedance restriction condition may be satisfied.

Such impedance restriction conditions may be provided in order to efficiently separate a transmission signal and a reception signal having the same frequency, even without using an active element.

The transmission terminal impedance and the reception terminal impedance may be specified by an RF signal line printed on a PCB. That is, physical shapes or characteristics (such as widths, intervals, etc.) of an RF signal line printed on the transmission unit (140) and the reception unit (150) may be adjusted to have desired impedance values.

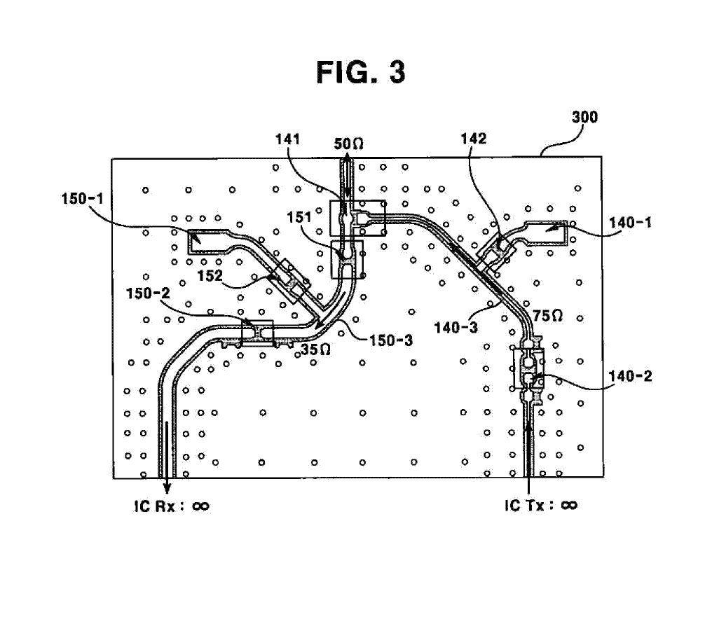

FIG. 2 is an exemplary view illustrating an actual feature of the SPDT switch (100). Referring to FIG. 2, the transmission unit (140) and the reception unit (150) may be composed using a PCB (Printed Circuit Board). In addition, an antenna port (110), a transmission port (120), and a reception port (130) may be connected to the PCB.

FIG. 3 is an exemplary view illustrating an exemplary embodiment a posterior portion of the PCB (300) composing the SPDT switch (100).

The transmission unit (140) may include a first impedance matching unit (141) configured to match the antenna impedance and the transmission terminal impedance, a first switching element (142) configured to remove an RF signal of an RF signal line (140-3) by being switched contingent upon appliance of electricity through a voltage supply line (140-1), and a first DC blocking capacitor (140-2) configured to remove DC component of a signal transmitted from a transmission port (120).

The reception unit (150) may include a second impedance matching unit (151) configured to match the antenna impedance and the transmission terminal impedance, a second switching element (152) configured to remove an RF signal of an RF signal line (150-3) by being switched contingent upon appliance of electricity through a voltage supply line (150-1), and a second DC blocking capacitor (150-2) configured to remove DC component of a signal received through an antenna (101).

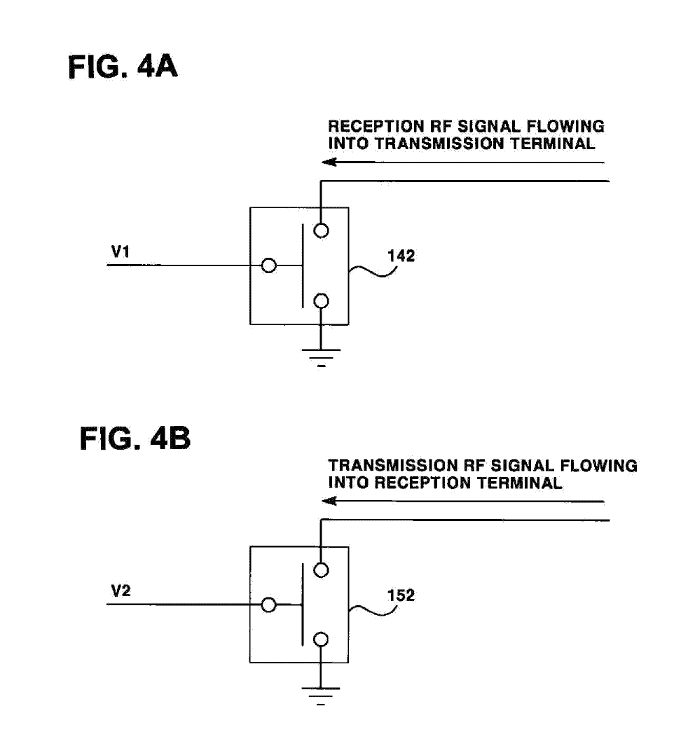

FIGS. 4A and 4B are exemplary views to describe operations of the first switching element (142) and the second switching element (152). The first switching element (142) may be turned On/Off by voltage (V1) applied to the voltage supply line (140-1), and the second switching element (152) may be turned ON/OFF by voltage (V2) applied to the voltage supply line (150-1), respectively.

To describe more particularly, the first switching element (142) may be controlled in an OFF status, and the second switching element (152) may be controlled in an ON status, when the SPDT switch (100) performs a transmitting operation. On the contrary, the first switching element (142) may be controlled in an ON status, and the second switching element (152) may be controlled in an OFF status, when the SPDT switch (100) performs a receiving operation.

The first switching element (142) and the second switching element (152) may perform a function to allow input signals to flow out through the earth, when the first switching element (142) and the second switching element (152) are controlled in ON status.

That is, the transmission signal that has flown into the reception unit (150) may be removed during transmitting operation. Here, the impedance of an IC (a reception IC connected at the reception port, not illustrated) viewed from the transmission signal is infinite, such that all signals are allowed to flow into the second switching element (152) having comparatively very small amount of impedance. Therefore, the relevant IC may not be directly influenced.

In addition, the reception signal that has flown into the transmission unit (140) may be removed during receiving operation. Here, the impedance of an IC (a transmission IC connected at the transmission port, not illustrated) from the reception signal is infinite, such that all signals are allowed to flow into the first switching element (142) having comparatively very small amount of impedance. Therefore, the relevant IC may not be directly influenced.

Hereinafter, the operations of the SPDT switch (100) will be described in detail with reference to FIGS. 3 and 4.

Generally, loss of signal occurs due to reflection in a signal transmission circuit, when impedance difference is generated. Therefore, impedance marching design is required in order to minimize loss of signal.

In this regard, the first impedance matching unit (141) may function to match the antenna impedance and the transmission terminal impedance in order to reduce loss of transmission signal, and the second impedance matching unit (151) may function to match the antenna impedance and the reception terminal impedance in order to reduce loss of reception signal.

The first impedance matching unit (141) and the second impedance matching unit (151) may be composed using a combination of an inductor and a capacitor.

Each of the transmission unit (140) and the reception unit (150) of the SPDT switch (100) may have different impedance of its own. The transmission unit (140) and the reception unit (150) may form a reversed T-shaped structure, and may transmit or receive a signal having the same frequency through a single antenna (101). Here, the flow of transmission/reception signals may be controlled using a principle that a signal is transmitted to a line having comparatively low impedance difference.

For example, it will be described an exemplary embodiment where the reception terminal impedance for receiving signals is 35Ω, the transmission terminal impedance is 75Ω, and the antenna impedance is 50Ω.

When viewed from the antenna (101), the difference from the reception terminal impedance is 15Ω, and the difference from the transmission terminal impedance is 25Ω. Therefore, most of the signals received through the antenna (101) are allowed to flow into the reception unit (150).

As illustrated in FIG. 4A, some part of the reception signals flowing into the transmission unit (140) may flow through the first switching element (142) being switched by the voltage (V1) applied to the voltage supply line (140-1), such that the influence of the reception signal to the transmission terminal can be minimized.

When viewed from the transmission signal, the difference from the antenna impedance is 25Ω, and the difference from the reception terminal impedance is 40Ω. Therefore, most of the transmission signals are radiated to the antenna (101) having comparatively small amount of impedance, such that only some part of the transmission signals can flow into the reception into the reception unit (150).

As illustrated in FIG. 4B, the some part of the transmission signals flowing into the reception unit (150) may flow through the second switching element (152) being switched by the voltage (V2) applied to the voltage supply line (150-1), such that the influence of the transmission signal to the reception terminal can be minimized.

Any active element capable of being turned ON/OFF may be optionally employed as the first switching element (142) and the second switching element (152).

When performing receiving operation, weak signals may be received by the antenna (101), and the received signals may be amplified. Therefore, the higher performance can be exhibited as the smaller difference from the antenna impedance is. In addition, the influence of the transmission signal to the reception terminal can be reduced as the difference between the transmission terminal impedance and the reception terminal impedance becomes greater.

The transmission terminal impedance and the reception terminal impedance may be implemented by adjusting physical shapes or characteristics of RF signal lines (140-3, 150-3) printed on the PCB (300).

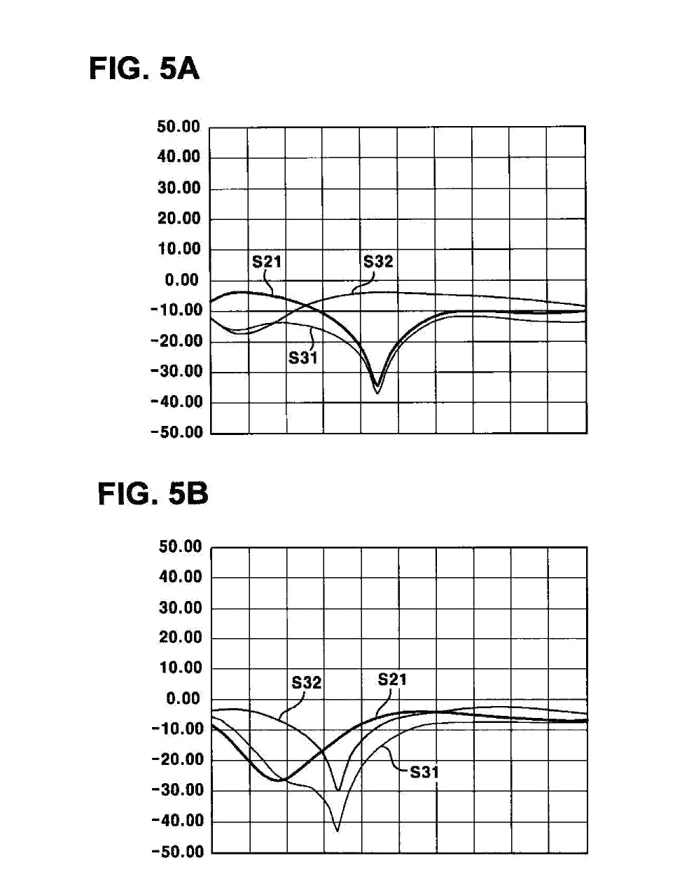

FIGS. 5A and 5B are views illustrating an exemplary embodiment of S-parameter measured by a network analyzer. According to the exemplary embodiment of FIGS. 5A and 5B, the reception port is a first port, the antenna port is a second port, and the transmission port is a third port.

FIG. 5A relates to the receiving operation. Referring to FIG. 5A, S31 parameter relating between the reception port and the transmission port exhibits a characteristic similar to that of S21 parameter relating to the receiving operation. Therefore, it is illustrated that separation between the transmission signal and the reception signal has been successfully accomplished.

FIG. 5B relates to the transmitting operation. Referring to FIG. 5B, S31 parameter relating between the reception port and the transmission port exhibits a characteristic similar to that of S32 parameter relating to the transmitting operation. Therefore, it is illustrated that separation between the transmission signal and the reception signal has been successfully accomplished.

The exemplary embodiments described in the above are proposed in order to facilitate understanding of the present disclosure. Thus, the present disclosure is not limited by the exemplary embodiments described in the above. Therefore, it will be apparent that the persons who skilled in the art of the present disclosure may easily perform various transformed or modified embodiments within the limit of the claimed technical spirit of the present disclosure.

What is claimed is:

1. An SPDT (Single-Pole-Double-Throw) switch configured to transmit and receive signals in a same frequency through an antenna, the SPDT switch comprising:
a reception unit configured to receive a signal through the antenna, and
a transmission unit configured to transmit a signal through the antenna,
wherein a difference between an antenna impedance and a reception terminal impedance of the reception unit is less than a difference between the antenna impedance and a transmission terminal impedance of the transmission unit, and a difference between the transmission terminal impedance and the antenna impedance is less than a difference between the transmission terminal impedance and the reception terminal impedance.

2. The SPDT switch of claim 1, wherein the transmission terminal impedance and the reception terminal impedance are specified by an RF signal line printed on a PCB.

3. The SPDT switch of claim 1, wherein the transmission terminal impedance is 75Ω, and the reception terminal impedance is 35Ω.

4. The SPDT switch of claim 1, wherein:
the transmission unit includes: a first impedance matching unit configured to match the antenna impedance and the transmission terminal impedance; and a first switching element configured to remove an RF signal of an RF signal line by being switched contingent upon appliance of electricity, and
the reception unit includes: a second impedance matching unit configured to match the antenna impedance and the reception terminal impedance; and a second switching element configured to remove an RF signal of an RF signal line by being switched contingent upon appliance of electricity.

5. The SPDT switch of claim 4, further comprising:
a first DC blocking capacitor configured to remove DC component of a signal transmitted from a transmission port; and
a second DC blocking capacitor configured to remove DC component of a signal received through the antenna.

6. The SPDT switch of claim 4, wherein the first impedance matching unit and the second impedance matching unit perform impedance matching using a combination of an inductor and a capacitor.
